(19) United States
(12) Patent Application Publication
(10) Pub. No.: US 2008/0164567 A1
(43) Pub. Date: Jul. 10, 2008

(54) BAND GAP REFERENCE SUPPLY USING NANOTUBES

(75) Inventors: King F. Lee, Schaumburg, IL (US); Barry W. Herold, Barrington, IL (US)

Correspondence Address: MOTOROLA, INC., 1303 EAST ALGONQUIN ROAD, IL01/3RD, SCHAUMBURG, IL, 60196, US

(73) Assignee: MOTOROLA, INC., Schaumburg, IL (US)

(21) Appl. No.: 11/621,281

(22) Filed: Jan. 9, 2007

(51) Int. Cl. H01L 29/00

(52) U.S. Cl. 257/536

(57) ABSTRACT

A current and/or voltage band gap reference circuit includes a current mirror circuit having first, second and third current outputs, a first resistive element, and first and second nanotube transistors. The nanotube diameter of the first transistor is different to the nanotube diameter of the second transistor, allowing variable band-gaps to be achieved. A method for designing the circuit includes selection of the nanotube diameters.

### FIELD OF THE INVENTION

The present invention relates generally to the use of nanotubes in electrical circuits and, in particular, to circuits for voltage and current reference supplies.

### BACKGROUND

Carbon nanotubes (CNTs) are allotropes of carbon that take the form of cylindrical carbon molecules. First observed in the 1950's, CNT's have novel properties that make them potentially useful in a wide variety of applications in nanotechnology, electronics, optics and other fields of materials science. They exhibit extraordinary strength and unique electrical properties, and are efficient conductors of heat. Inorganic nanotubes have also been synthesized. The diameter of a single-walled nanotube (SWNT) is typically 1 to 30 nm, and its length can be up to orders of micrometers. The band gap for conduction electrons and therefore the electrical conductivity of a carbon nanotube can be adjusted by means of its tube parameters, such as, for example, its diameter and its chirality.

Nanotubes can be produced not only from carbon but also from other elements such as boron nitride.

Single-walled nanotubes (SWNT) are a very important variety of carbon nanotube because they exhibit important electric properties that are not shared by the multi-walled carbon nanotube (MWNT) variants. Single-walled nanotubes are the most likely candidate for miniaturizing electronics past the micro electromechanical scale that is currently the basis of modern electronics. The most basic building block of these systems is the electric wire, and SWNTs can be excellent conductors. One useful application of SWNTs is in the development of intramolecular field effect transistors (FETs). The production of the first intra-molecular logic gate using SWNT FETs has recently become possible and CNT FET's have been proposed for multi-level logic circuits. In particular, the geometry dependent threshold voltage of a CNT FET has been used to design a family of ternary logic devices.

### BRIEF DESCRIPTION OF THE FIGURES

The accompanying figures, in which like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 is a block diagram of an exemplary nanotube band gap current/voltage reference circuit in accordance with some embodiments of the invention.

FIG. 2 is a circuit diagram of an exemplary nanotube band gap current reference circuit in accordance with some embodiments of the invention.

FIG. 3 is a circuit diagram of a further exemplary nanotube band gap current reference circuit in accordance with some embodiments of the invention.

FIG. 4 is a circuit diagram of an exemplary nanotube band gap voltage reference circuit in accordance with some embodiments of the invention.

FIG. 5 is a circuit diagram of a further exemplary nanotube band gap voltage reference circuit in accordance with some embodiments of the invention.

FIG. 6 is a flow chart of a method for nanotube band gap current/voltage reference circuit design, in accordance with some embodiments of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION

Before describing in detail embodiments that are in accordance with the present invention, it should be observed that the embodiments reside primarily in combinations of method steps and apparatus components related to the use of nanotubes in band gap circuits. Accordingly, the apparatus components and method steps have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

In this document, relational terms such as first and second, top and bottom, and the like may be used solely to distinguish one entity or action from another entity or action without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element preceded by “comprises . . . a” does not, without more constraints, preclude the existence of additional identical elements in the process, method, article, or apparatus that comprises the element.

Carbon nanotubes have many properties, from their unique dimensions to an unusual current conduction mechanism, that make them ideal components of electrical circuits. It is known that as the nanotube diameter increases, more wavevectors are allowed in the circumferential direction. Since the band gap in semiconducting nanotubes is inversely proportional to the tube diameter, the band gap (the energy difference between the top of the valence band and the bottom of the conduction band, which is the energy that an electron must reach in order to flow free in a semiconductor) approaches zero at large diameters. For example, at a nanotube diameter of about 3 nm, the band gap becomes comparable to thermal energies at room temperature.

The tube diameter d is related to the chirality vector (n, m) by

d=\sqrt{n²+m²+nm}×0.0783 nanometers.

The band gap E_{g} is related to the diameter d (in nanometers) by

$${E}_{g} = \frac{4 ℏ {v}_{F}}{3 d} ,$$

where [symbol] is the reduced Planck constant, [symbol] =h/2π, and v_{F} is the Fermi velocity.

Different band gaps can be engineered from the same basic material (carbon) by manipulating the diameter of the nanotube during manufacture.

In accordance with some embodiments of the present invention, carbon nanotubes having different band gaps are combined to create analog or digital circuits.

The principle of band-gap silicon circuits is well known. For example, a silicon band gap voltage reference circuit relies on two groups of transistors running at different emitter current densities. The rich transistor will typically run at a multiple (10 times, for example) of the density of the lean ones, and will cause a voltage difference between the base-emitter voltages of the two groups. This difference voltage is usually amplified and added to a collector/emitter voltage. The total of these two voltages adds up to voltage that is approximately the band gap of silicon.

The silicon has a single band gap determined by its molecular structure. In contrast, the band gap of a carbon nanotube is dependent on its diameter. In a CNT FET, the band gap is related to the threshold voltage V_{TH}, since the energy bands move up, or down, due to application of a gate control voltage V_{G}.

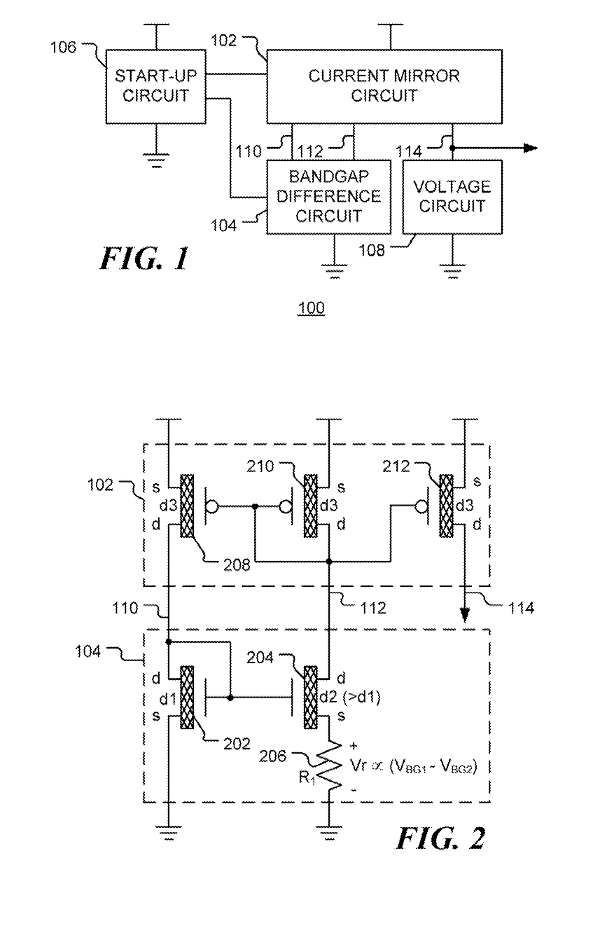

FIG. 1 is a block diagram of an exemplary nanotube band gap current/voltage reference circuit in accordance with some embodiments of the invention. Referring to FIG. 1, the circuit 100 includes a current mirror circuit 102, a band gap difference circuit 104, a start-up circuit 106 and, optionally, a voltage circuit 108. The current mirror circuit 102 produces 3 current outputs, 110, 112 and 114.

FIG. 2 is an example carbon nanotube band gap current reference circuit in accordance with some embodiments of the invention. In the embodiment shown in FIG. 2, band gap difference circuit 104 comprises a first transistor 202, which includes a first nanotube. The first transistor is configured as a diode connected device, with the drain couple to the gate. The drain is also coupled to the first current output 110. The transistor source is coupled to an electrical ground. A second transistor 204, which includes a second nanotube, has a drain coupled to the second current output 112, a source coupled to the electrical ground through a resistive element 206 and a gate coupled to the gate of the first transistor 202. The diameter of the first nanotube is different to the diameter of the second nanotube.

The current mirror circuit 102 comprises three P-channel transistors, 208, 210 and 212. The gates of the transistors are coupled and a voltage V_{DD} is applied to the circuit. The transistors 208, 210 and 212 have nominally the same characteristics and form a current mirror that balances the currents in current outputs 110, 112 and 114. In FIG. 2, the transistors 208, 210 and 212 are shown as P-channel nanotube transistors, however other current mirror circuits, including those using silicon transistors, may be used without departing from the present invention.

A steady state condition exists in which current flows through all of the transistors in the current mirror circuit 102. This steady state may be attained by use of a start-up circuit (106 in FIG. 1). Such start-up circuits are commonly used in conventional silicon band gap reference circuits and are well known to those of ordinary skill in the art.

Referring again to FIG. 2, the third current output 114 provides a reference current.

The transistors 202 and 204 may be carbon nanotube field effect transistors (CNT FET's). In the embodiment shown in FIG. 2, the transistors 202 and 204 are N-channel transistors. The diameter of the nanotube of transistor 204 is greater than the diameter of the nanotube in transistor 202. If the transistors are similar in other regards, the threshold voltage V_{TH2} of transistor 204 is less than the threshold voltage V_{TH1} of the transistor 202.

Since current output 110 is set to be equal to current output 112 by the current mirror circuit 102 and the diameter of the first nanotube is smaller than the diameter of the second nanotube, the current density in the second transistor 204 is lower than that in the first transistor 202. The voltage across resistive element 206 is proportional to the difference in threshold voltages, which is, in turn, dependent upon the difference in band gap voltages. This voltage develops a current across the resistive element 206. This current is the same current flowing through transistor 204 and the output current 112. The output current 114 is set to be equal to current output 112 by the current mirror circuit 102. Therefore, the output current 114 is also proportional to the difference in threshold voltages, which is, in turn, dependent upon the difference in band gap voltages of the first and second nanotubes.

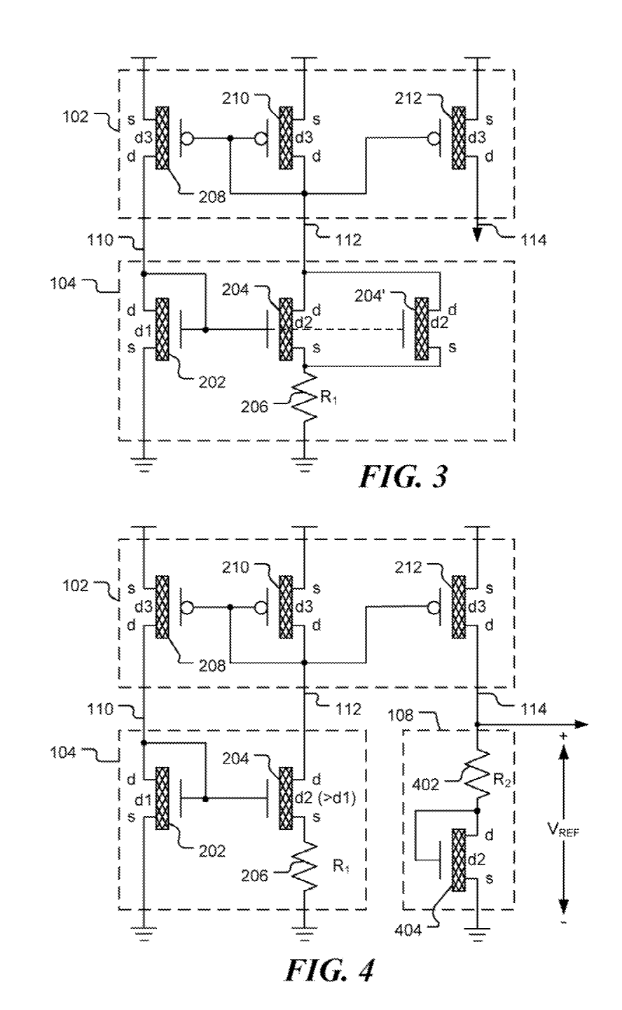

FIG. 3 is a circuit diagram of a further exemplary nanotube band gap current reference circuit in accordance with some embodiments of the invention. In the circuit shown in FIG. 3, the single second transistor 204 is replaced by a plurality of transistors (204, 204′. etc.) arranged in parallel. The number of transistors, and their nanotube diameters, may be chosen by a circuit designer to achieve desired characteristics of the output current 114.

FIG. 4 is an exemplary carbon nanotube band gap voltage reference circuit in accordance with some embodiments of the invention. The circuit includes a voltage circuit 108 coupled between the current output 114 and ground. The difference in potentials across the voltage circuit 108 provides a reference voltage. In this embodiment, the voltage circuit 108 comprises a resistive element 402 and a nanotube transistor 404. The transistor may have the same characteristics (including the same nanotube diameter) as the transistor 204 in the band gap difference circuit 104. The drain of transistor 404 is coupled to the gate, so the transistor functions as a diode.

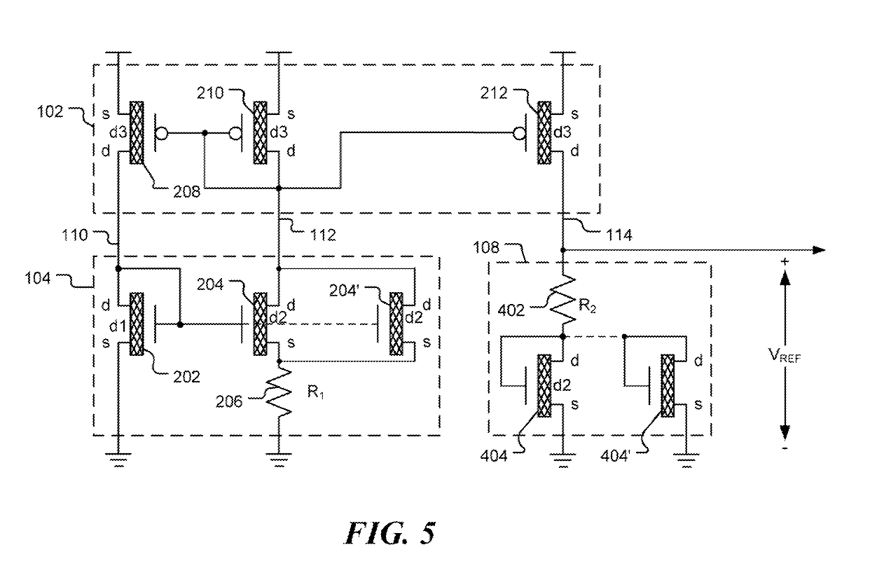

FIG. 5 is a further exemplary carbon nanotube band gap voltage reference circuit in accordance with some embodiments of the invention. In the circuit shown in FIG. 5, the single second transistor 204 is replaced by a plurality of transistors (204, 204′. etc.) arranged in parallel. The number of transistors, and their nanotube diameters, may be chosen by a circuit designer to achieve desired characteristics of the output current 114.

The corresponding transistor 404 in the voltage circuit 108 may also be replaced by a plurality of transistors (404, 404′. etc.) arranged in parallel. The number of transistors, and their nanotube diameters, may be chosen to match transistors 204, 204′ etc.

The use of nanotube transistors in voltage and current reference circuits provides a circuit designer with additional parameters, thereby increasing the flexibility in the circuit design. In contrast to silicon transistors, which have a single band gap of 1.205V, carbon nanotube transistors have band gaps that depend upon their diameter. The nanotube diameter may be varied to achieve a desired reference voltage.

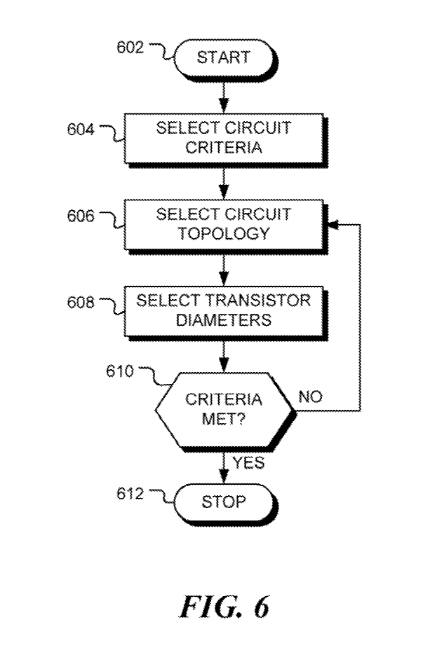

FIG. 6 is a flow chart of a method for nanotube band gap current/voltage reference circuit design, in accordance with some embodiments of the invention. Following start block 602 in FIG. 6, a designer selects the criteria by which a current/voltage reference circuit is to be designed at block 604. At block 606, the designer selects a circuit topology. The circuit topology may be similar to the exemplary circuits described above, or may be other band gap circuits known to those of ordinary skill in the art. At block 608, the designer selects the diameters of nanotubes included in at least two of the transistors in the circuit. The nanotube diameters are design parameters, and different nanotubes may have different diameters. The nanotube diameters determine the band gaps and threshold voltages of the transistors. At block 610, the circuit is analyzed to determine if the selected criteria have been met. If not, as depicted by the negative branch from decision block 610, flow returns to block 606, where a further design iteration is selected. If the criteria are met, as depicted by the positive branch from decision block 610, the design is complete and the process terminates at block 612. Some or all of the steps of the design process may be automated and performed by a computer.

The circuit topology and the nanotube diameters are output, in printed or electronic format for example, as at least part of the circuit design.

In the foregoing specification, specific embodiments of the present invention have been described. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of the present invention. The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

What is claimed is:

1. A band gap reference circuit comprising:
a current mirror circuit having first, second and third current outputs;
a first resistive element;
a first transistor comprising a first nanotube and having a drain coupled to the first current output, a gate coupled to the drain and a source coupled to an electrical ground, and
a second transistor comprising a second nanotube and having a drain coupled to the second current output, a source coupled to the electrical ground through the first resistive element and a gate coupled to the gate of the first transistor;
wherein the diameter of the first nanotube is different to the diameter of the second nanotube and wherein the third current output provides a reference current.

2. A band gap reference circuit in accordance with claim 1, wherein the current mirror circuit comprises:
a third transistor coupled to the first transistor and operable to provide the first current;
a fourth transistor coupled to the second transistor and operable to provide the second current; and
a fifth transistor operable to provide the third current,
wherein the gates of the third, fourth and fifth transistors are coupled.

3. A band gap reference circuit in accordance with claim 2, wherein third, fourth and fifth transistors each comprise a nanotube.

4. A band gap reference circuit in accordance with claim 2, wherein third, fourth and fifth transistors each comprise a P-channel transistor.

5. A band gap reference circuit in accordance with claim 1, wherein the current density in the second transistor is different from the current density in the first transistor.

6. A band gap reference circuit in accordance with claim 1, wherein the current density in the second transistor is lower than the current density in the first transistor.

7. A band gap reference circuit in accordance with claim 1, wherein the first and second transistors comprise N-channel transistors.

8. A band gap reference circuit in accordance with claim 1, further comprising a start-up circuit operable to control the state of the band gap reference circuit during and following start-up.

9. A band gap reference circuit in accordance with claim 1, further comprising:
a second resistive element, and
a sixth transistor;
wherein the second resistive element and the sixth transistor are coupled in series to form a voltage circuit between the third current output of the current mirror circuit and the electrical ground, resulting in a reference voltage across the voltage circuit.

10. A band gap reference circuit in accordance with claim 9, wherein the sixth transistor includes a nanotube of substantially the same diameter as the nanotube of the second transistor.

11. A band gap reference circuit in accordance with claim 1, further comprising:
at least one additional transistor coupled in parallel with the second transistor, each gate of the at least one additional transistor being coupled to the gate of the second transistor, each drain of the at least one additional transistor being coupled to the drain of the second transistor, and each source of the at least one additional transistor being coupled to the source of the second transistor.

12. A band gap reference circuit in accordance with claim 11, wherein the at least one additional transistor coupled in parallel with the second transistor each include a nanotube of substantially the same diameter as the nanotube of the second transistor.

13. A band gap reference circuit in accordance with claim 11, further comprising:
a second resistive element, and
a plurality of sixth transistors coupled in parallel with each other;
wherein the second resistive element is coupled in series with the plurality of sixth transistors to form a voltage circuit between the third current output of the current mirror circuit and the electrical ground, resulting in a reference voltage across the voltage circuit.

14. A method for generating a design for a nanotube band gap current/voltage reference circuit: comprising:
selecting a circuit topology comprising a plurality of nanotube transistors;
selecting the nanotube diameters of a plurality of nanotube transistors; and
outputting a design comprising the circuit topology and the nanotube diameters;
wherein the nanotube diameter of a first nanotube transistor of the plurality of nanotube transistors is different to the nanotube diameter of a second nanotube transistor of the plurality of nanotube transistors.

15. A method in accordance with claim 14, further comprising:
selecting criteria by which the current/voltage reference circuit is to be designed;
analyzing the reference circuit to determine if the selected criteria have been met; and
while the criteria are not met, repeating the steps of:
selecting a circuit topology including a plurality of nanotube transistors; and
selecting the nanotube diameters plurality of nanotube transistors of the first and second nanotube transistors.

16. A method in accordance with claim 14, performed at least partially by a computer.

17. A method in accordance with claim 14, wherein:
the circuit topology comprises a current mirror circuit having first, second and third current outputs and a first resistive element;
the first nanotube transistor comprises a first nanotube and having a drain coupled to the first current output, a gate coupled to the drain and a source coupled to an electrical ground;
the second nanotube transistor comprises a second nanotube and having a drain coupled to the second current output, a source coupled to the electrical ground through the first resistive element and a gate coupled to the gate of the first nanotube transistor; and
the third current output comprises a reference current output.

18. A method in accordance with claim 17, wherein the circuit topology further comprises a second resistive element and third transistor, and wherein the second resistive element and the third transistor are coupled in series to form a voltage circuit between the third current output of the current mirror circuit and the electrical ground, resulting in a reference voltage across the voltage circuit.
